(19) United States
(12) Patent Application Publication
(10) Pub. No.: US 2014/0042407 A1
(43) Pub. Date: Feb. 13, 2014

(54) BIOHYBRID PHOTOELECTROCHEMICAL ENERGY CONVERSION DEVICE

(71) Applicant: Vanderbilt University, Nashville, TN (US)

(72) Inventors: David E. Cliffel, Nashville, TN (US); Gabriel LeBlanc, Nashville, TN (US); G. Kane Jennings, Nashville, TN (US)

(73) Assignee: Vanderbilt University, Nashville, TN (US)

(21) Appl. No.: 13/953,342

(22) Filed: Jul. 29, 2013

Related U.S. Application Data
(60) Provisional application No. 61/680,875, filed on Aug. 8, 2012.

(51) Int. Cl. H01L 51/44

(52) U.S. Cl. CPC H01L 51/441
USPC 257/40

(57) ABSTRACT

One aspect of the present disclosure relates to a biohybrid, photoelectrochemical energy conversion device including a first electrode, a second electrode, and a multilayer photoconductive organic film interposed between the first and second electrodes. The second electrode is formed from a semiconductor material. Each layer of the photoconductive organic film includes at least one light harvesting complex.

### RELATED APPLICATION

This application claims the benefit of U.S. Provisional Patent Application Ser. No. 61/680,875, filed Aug. 8, 2012, the entirety of which is hereby incorporated by reference for all purposes.

### TECHNICAL FIELD

The present disclosure relates generally to photosensitive devices, and more particularly to a photoelectrochemical energy conversion device comprising at least one light harvesting complex for trapping and converting incident light to electrochemical energy.

### BACKGROUND

Green plants and photosynthetic bacteria capture and utilize sunlight by means of molecular electronic complexes or reaction centers that are embedded in their membranes. In oxygenic plants, photon capture and conversion of light energy into chemical energy take place in pigment-protein complexes known as Photosystem I (PSI) and Photosystem II (PSII) reaction centers. Photosynthesis requires PSII and PSI working in sequence, using water as the source of electrons and CO₂ as the terminal electron acceptor. The two reaction centers use a special pair of chlorophyll molecules as the primary electron donor and chlorophyll or pheophytin as the primary electron acceptor. Following excitation, transfer of an electron from the excited primary donor to the primary acceptor occurs within picoseconds, a process characterized by high quantum efficiency and minimal side reactions.

For the PSI reaction center, the midpoint oxidization potential generated by the primary electron donor (P₇₀₀) is about +0.4 V, and the corresponding reduction potential generated by the electron acceptor (4Fe-4S center) is about −0.7 V. Since the PSI reaction center is one of the pigment-protein complexes responsible for the photosynthetic conversion of light energy to chemical energy, these reaction centers may be used as an electronic component in a variety of different devices, such as spatial imaging devices, solar batteries, optical computing and logic gates, optoelectronic switches, photonic A/D converters, and thin film “flexible” photovoltaic structures. Attempts have been made to incorporate the PSI reaction center in such devices; however, these devices suffer from very low efficiencies and short lifetimes.

### SUMMARY

The present disclosure relates generally to photosensitive devices, and more particularly to a photoelectrochemical energy conversion device comprising at least one light harvesting complex for trapping and converting incident light to electrochemical energy.

One aspect of the present disclosure relates to a biohybrid, photoelectrochemical energy conversion device comprising a first electrode, a second electrode, and a multilayer photoconductive organic film interposed between the first and second electrodes. The second electrode is comprised of a semiconductor material. Each layer of the photoconductive organic film includes at least one light harvesting complex.

### BRIEF DESCRIPTION OF THE DRAWINGS

The foregoing and other features of the present disclosure will become apparent to those skilled in the art to which the present disclosure relates upon reading the following description with reference to the accompanying drawings, in which:

FIGS. 1A-B are schematic representations showing an assembled (FIG. 1A) and exploded (FIG. 1B) biohybrid photoelectrochemical energy conversion device constructed in accordance with one aspect of the present disclosure;

FIG. 2A illustrates photochronoamperometric analysis of Photosystem I (PSI)-modified (bold line) and unmodified (light line) P-doped silicon (FIG. 2A). Measurements made with or without a PSI film (1.5±0.2 μm) in 0.2 mM methyl viologen, 0.1 M KCl, with a Ag/AgCl reference electrode and a platinum mesh counter electrode. The working electrode was held at the open circuit potential, and the light (633 nm high-pass filtered) was turned on and off at 10 s and 30 s, respectively;

FIG. 2B shows electron flow through the PSI-modified P-doped silicon electrode to the platinum counter electrode. Methyl viologen was used to complete the circuit. The potentials for P₇₀₀⁺ and F_{b}⁻ are taken from previous voltammetric measurements;

FIGS. 3A-D are a series of graphs illustrating photocurrent density (n=4) with PSI (gray) and without (black) as a function of redox mediator formal potential. Doping type and doping density of the silicon substrate were varied as follows: lightly N-doped (FIG. 3A); heavily N-doped (FIG. 3B); lightly P-doped (FIG. 3C); and heavily P-doped (FIG. 3D). Measurements made with or without a PSI film (1.5±0.2 μm) in 0.2 mM redox mediator, 0.1 M KCl, with a Ag/AgCl reference electrode and a platinum mesh counter electrode. Values were determined by taking the difference between the current density in the dark and the current density after 10 s of illumination (633 nm high-pass filtered);

FIG. 4 is a graph comparing photocurrent density and mediator concentration. Unmodified heavily P-doped silicon (black) or heavily P-doped silicon modified with a 0.9 μm±0.1 μm film of PSI (gray) was used as the working electrode. Photocurrent densities (n=4) were determined by taking the difference between the current density in the dark and the current density after 10 s of illumination (633 nm high-pass filtered);

FIG. 5 is a graph of photocurrent density as a function of PSI film thickness. Photocurrent measurements (n=4) were made using 0.2 mM methyl viologen with 0.1 M KCl as the supporting electrolyte. Photocurrent density values were determined by taking the difference between the current density in the dark and the current density after 10 s of illumination (633 nm high-pass filtered). Film thickness was determined using profilometry; and

FIG. 6 shows photovoltage analysis of PSI-modified (green) and unmodified (black) heavily P-doped silicon. The open circuit potential for modified and unmodified samples was taken in an electrochemical mediator solution consisting of 0.2 M methyl viologen and 0.1 M KCl. The samples were illuminated from 10 s to 30 s. PSI film thickness was 2.0±0.3 μm.

### DETAILED DESCRIPTION

Unless defined otherwise, all technical and scientific terms used herein have the same meaning as is commonly understood by one of skill in the art to which the present disclosure pertains.

In the context of the present disclosure, the term “electrode” can refer to a medium or material capable of delivering photogenerated power to an external circuit or providing a bias voltage to a device. That is, an electrode can provide the interface between photoconductively active regions of a device and a wire, lead, trace, or other means for transporting charge carriers to or from the external circuit.

As used herein, a medium or material can be “transparent” when the medium or material permits at least about 50% of the ambient electromagnetic radiation in relevant wavelengths to be transmitted through the medium or material. Similarly, a medium or material that permits some but less than about 50% transmission of ambient electromagnetic radiation in relevant wavelengths may be considered “semi-transparent”.

As used herein, the term “photoconductive” can generally refer to the process in which electromagnetic radiant energy is absorbed and thereby converted to excitation energy of electric charge carriers so that the carriers can conduct (i.e., transport) electric charge in a material.

As used herein, the terms “photoconductor” and “photoconductive material” can refer to semiconductor materials which are chosen for their property of absorbing electromagnetic radiation of selected spectral regions to generate electric charge carriers.

As used herein, the term “semiconductor” can refer to one or a combination of materials that can conduct electricity when charge carriers are induced by thermal or electromagnetic excitation.

As used herein, the term “light harvesting complex” can refer to a complex of at least one polypeptide and other small molecules (e.g., chlorophyll and pigment molecules), which when integrated together work as a functional unit converting light energy to chemical energy. In some instances, light harvesting complexes of the present disclosure are present in, and can be derived from, photosynthetic organisms (i.e., organisms that convert light energy into chemical energy). Examples of photosynthetic organisms can include, but are not limited to, green plants (e.g., baby spinach), cyanobacteria, red algae, purple and green bacteria. In other instances, light harvesting complexes can be isolated from their natural site of synthesis and used as a component of the present disclosure in their wild-type form. In further instances, light harvesting complexes can be modified (e.g., an amino acid modification using recombinant DNA technology) from their wild-type form. In one example, a light harvesting complex can comprise Photosystem I (PSI). In another example, a light harvesting complex can comprise Photosystem II (PSII).

As used herein, the term “isolated” with reference to a light harvesting complex can refer to the photocatalytic polypeptide complex that has been at least partially removed from its natural site of synthesis (e.g., photosynthetic organism). In some instances, the light harvesting complex is not isolated from other members of the photocatalytic unit (i.e., chlorophyll and pigment) so that the complex remains functional. In other instances, an isolated light harvesting complex can be substantially free from other substances (e.g., other cells, proteins, nucleic acids, etc.) that are present in its in vivo location. One skilled in the art will appreciate that the activity of light harvesting complexes may be tested following isolation.

As used herein, the term “photocatalytic activity” can refer to the conversion of light energy to chemical energy. In one example, a light harvesting complex of the present disclosure can retain at least 20%, at least 30%, at least 40%, at least 50%, at least 60%, at least 70%, at least 80%, at least 90%, e.g., about 100% of the photocatalytic activity of a wild-type light harvesting complex in its in vivo environment. In some instances, a light harvesting complex can exhibit a photocatalytic activity greater than that of a wild-type light harvesting complex in its in vivo environment (e.g., where the light harvesting complex has been modified).

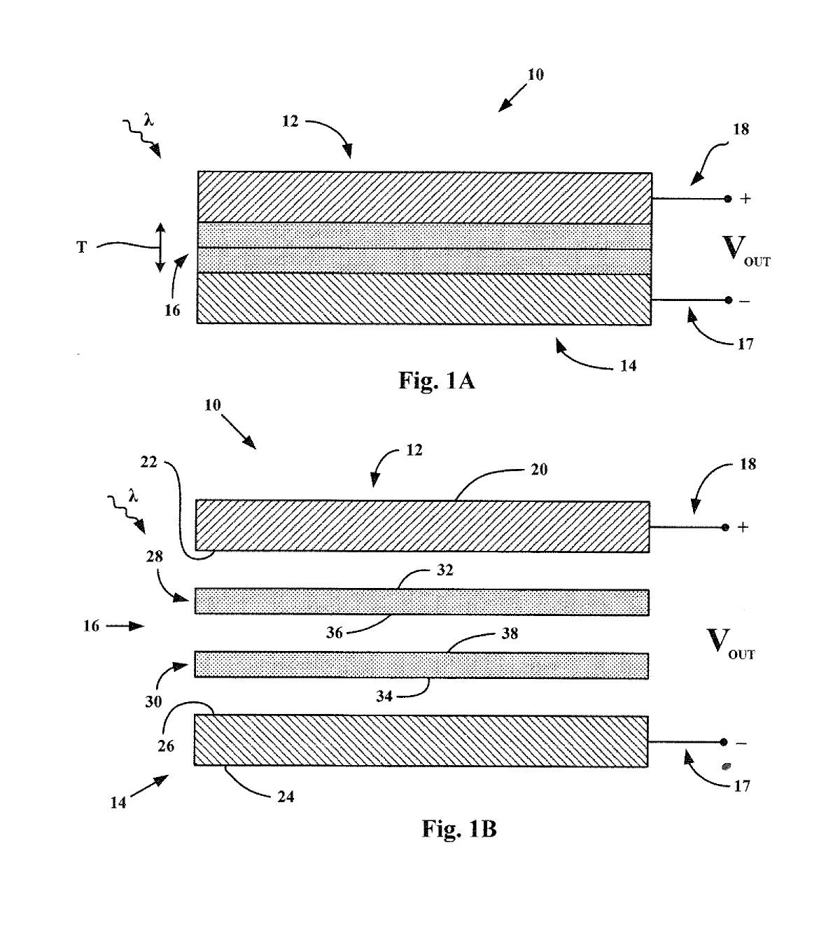

The present disclosure relates generally to photosensitive devices, and more particularly to a photoelectrochemical energy conversion device comprising at least one light harvesting complex for trapping and converting incident light to electrochemical energy. Using a biohybrid system comprising a multilayer PSI-containing film deposited on P-doped the inventors of the present disclosure sought to investigate: (1) how the doping type and doping concentration in silicon affect the photo-electrochemistry of the system; and (2) how the resulting photocurrent for the system can be optimized. Surprisingly, it was discovered that: (1) photocurrent enhancement with PSI occurred for heavily P-doped silicon; and (2) high concentrations of the electrochemical mediator methyl viologen provided improved photocurrent density. Without wishing to be bound by theory, it is believed that the observed photocurrent enhancement is due, at least in part, to a shift in the Fermi energy of silicon by introducing impurities (i.e., doping) into the silicon, which allows electrons to flow in a single direction via band alignment between the valence band of silicon and the P₇₀₀ reaction center of PSI. Based at least in part on this discovery, the present disclosure provides a biohybrid, photoelectrochemical energy conversion device 10 (FIGS. 1A-B) that may be used in a variety of photosensitive devices and systems.

In one aspect of the present disclosure, a biohybrid photoelectrochemical energy conversion device 10 can comprise a first electrode 12, a second electrode 14, and a multilayer photoconductive organic film 16 interposed between the first and second electrodes. The dimensions (e.g., length, width, thickness) of the device 10 can be varied depending upon the intended application of the device (e.g., as a component in a photosensitive device). In some instances, the dimensions of each of the first electrode 12, the second electrode 14, and the multilayer photoconductive organic film 16 can be the same. In other instances, one or more dimensions of the first electrode 12, the second electrode 14, and/or the multilayer photoconductive organic film 16 can be different. In one example, the device 10 can have a rectangular configuration as shown in FIGS. 1A-B. One skilled in the art will appreciate that the device 10 can have other shapes, such as square, circular, ovoid and triangular, as well as an irregular shape.

Generally, the first and second electrodes 12 and 14 can comprise any conducting medium, material, or component capable of delivering or receiving an electrical signal. In one example, the first electrode 12 can be configured as a counter electrode, meaning that the first electrode is configured to function in a polarity opposite the second electrode 14. The first and second electrodes 12 and 14 can provide electrical communication with one or more additional electronic devices, such as based on direct contact with the one or more additional electronic devices or via one or more conductive mechanisms (e.g., wires, traces, or leads), demonstrated as 18 and 19 in the example of FIGS. 1A-B. The term “electrical communication” can refer to the ability of a generated current to flow through or have an effect on, or a generated electric field to be transferred to or have an effect on, one or more coupled electronic components. In the example of FIGS. 1A-B, the biohybrid, photoelectrochemical energy conversion device 10 is configured to generate a signal (e.g., a voltage V_{OUT}) via the first and second electrodes 12 and 14, such as to indicate the presence of and/or magnitude of electromagnetic radiation λ.

The first electrode 12 can comprise a conducting medium, material, or component having oppositely disposed first and second major surfaces 20 and 22. Examples of materials or media that may be used to form the first electrode 12 can include, but are not limited to: metals (e.g., elementally pure metals and metal alloys), such as magnesium, silver, magnesium-silver, platinum, platinum-iridium, and the like; and metal substitutes (e.g., a material that is not a metal within the normal definition, but which has metal-like properties desired in certain applications), such as a doped (e.g., N- or P-doped) or undoped semiconductor material.

The first electrode 12 can be configured for admittance of light to the multilayer photoconductive organic film 16. In some instances, the first electrode 12 can include one or more apertures (not shown) for admittance of light to the multilayer photoconductive organic film 16. For example, the first electrode 12 can have a mesh-like configuration and be made of a metal, such as platinum. In other instances, the first electrode 12 can be made of a transparent or semi-transparent material that permits an amount of ambient electromagnetic radiation to be transmitted through the first electrode to the multilayer photoconductive organic film 16.

In another aspect, the second electrode 14 can include a first major surface 24 that is oppositely disposed from a second major surface 26. In some instances, the second electrode 14 can be comprised of a semiconductor material, such as silicon. The band gap for silicon is approximately 1.1 eV, making it photoactive in the visible region of the electromagnetic spectrum. Additionally, the valence band and conduction band for silicon (0.5 V and −0.6 V vs. NHE, respectively) roughly align with the P₇₀₀ and F_{b} redox centers of PSI (0.6 V and −0.45 V vs. NHE, respectively). As discussed above, the inventors of the present disclosure have discovered that silicon (and in particular heavily P-doped silicon) provides an improved substrate for the device 10. By doping or introducing impurities into silicon, for example, the Fermi energy of silicon can be shifted to optimize electron flow in a single direction. Thus, in some instances, the second electrode 14 can comprise P-doped silicon. In one example, the second electrode 14 can comprise heavily P-doped silicon (e.g., having a density of at least about 10¹⁶ cm⁻³). In other instances, the second electrode 14 can comprise one or a combination of other doped or un-doped semiconductor materials, such as an allotrope (e.g., graphene).

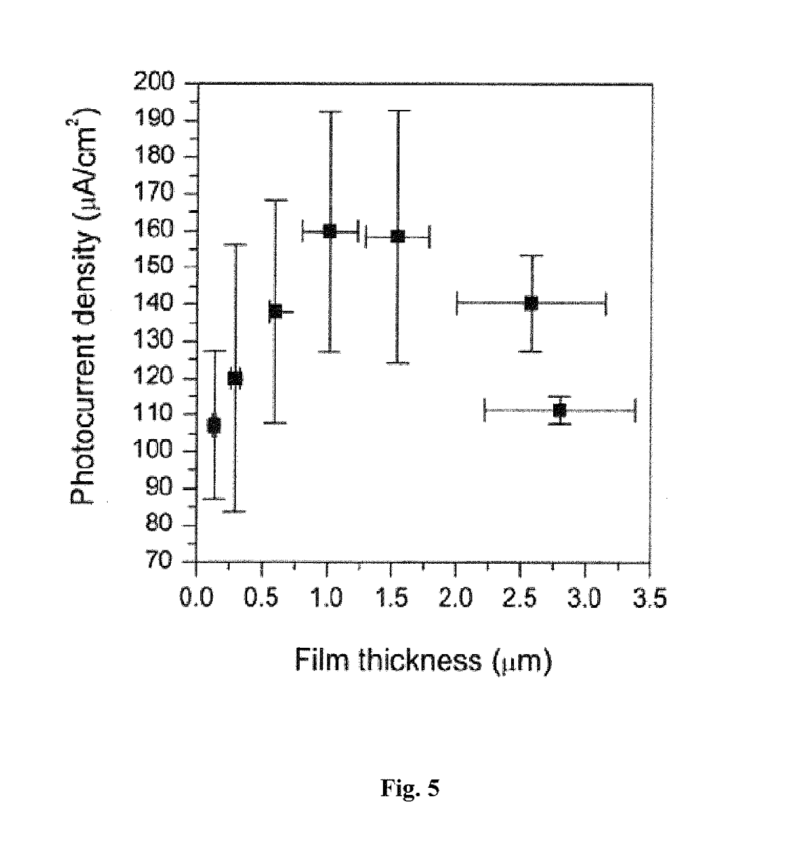

In another aspect, the device 10 includes a multilayer photoconductive organic film 16 interposed between the first and second electrodes 12 and 14. The multilayer photoconductive organic film 16 can be formed from two, three, four, five, or more individual layers. As shown in FIGS. 1A-B, for example, the multilayer photoconductive organic film 16 can be formed from a first layer 28 and a second layer 30. Each of the first and second layers 28 and 30 can include a first major surface 32 and 34 that directly contacts the second major surface 22 and 26 of each of the first and second electrodes 12 and 14, respectively, when the device 10 is assembled. Additionally, the first layer 28 can include a second major surface 36 that contacts a second major surface 38 of the second layer 30 when the device 10 is assembled. The multilayer photoconductive organic film 16 can have a thickness T defined by the collective thickness of each layer comprising the film. As shown in FIG. 5, the inventors of the present disclosure observed the highest photocurrents when the thickness T of the multilayer photoconductive organic film 16 was approximately 1 μm. It was also observed that beyond 2 μm, the photocurrent density begins to decline. Without wishing to be bound by theory, it is believed that light reaching the underlying semiconductor electrode plays an important role in the electron transfer process due, for example, to the increased population of electrons with the appropriate energy. Thus, in one example, the multilayer photoconductive organic film 16 can have a thickness T of about 0.5 μm to about 3 μm, or about 0.75 μm to about 1.75 μm (e.g., about 1 μm). In another example, the multilayer photoconductive organic film 16 can have a thickness T that imparts the device with the ability to generate a photocurrent density of about 130 μA/cm² to about 190 μA/cm² (e.g., about 155 μA/cm² to about 165 μA/cm²).

Each layer of the photoconductive organic film 16 can include one or more light harvesting complexes (not shown). In some instances, a light harvesting complex can be obtained or derived from a photosynthetic organism, such as green plants (e.g., baby spinach), cyanobacteria, red algae, purple and green bacteria. In other instances, a light harvesting complex can comprise PSI or PSII (e.g., if hydrogen production is desired) derived from a photosynthetic organism.

In one example, each layer of the photoconductive organic film 16 can include one or more PSI complexes. PSI is a protein-chlorophyll complex that has diodic properties and is part of the photosynthetic machinery within the thylakoid membrane. It is ellipsoidal in shape and has dimensions of about 5 by 6 nanometers. The PSI reaction center/core antenna complex contains about 40 chlorophylls per photoactive reaction center pigment (P₇₀₀). The chlorophyll molecules serve as antennae, which absorb photons and transfer the photon energy to P₇₀₀, where this energy is captured and utilized to drive photochemical reactions. In addition to the P₇₀₀ and the antenna chlorophylls, the PSI complex contains a number of electron acceptors. An electron released from P₇₀₀ is transferred to a terminal acceptor at the reducing end of PSI through intermediate acceptors, and the electron is transported across the thylakoid membrane. An electron is then transferred to the stroma surface and the hole remains on the lumen surface of PSI. After absorption of a photon, the energy is channeled to the primary electron donor at the base of the complex. Following exciton dissociation, the electron is transferred through three Fe₄S₄ clusters to the opposite surface. The result is an electron on the upper (stroma) surface and a hole on the lower (lumen) surface.

Due to the directed nature of electron transfer, conventional PSI-containing biohybrid systems typically require that PSI possess the correct orientation when deposited on a substrate because PSI preferentially deposits on hydrophilic surfaces with the electron transport vector perpendicular to the substrate. Advantageously, the issue of PSI orientation can be circumvented by the present disclosure through the use of a semiconductor (e.g., P-doped silicon), which shifts the Fermi energy of the semiconductor and thereby allows electrons to flow in a single direction (e.g., from the P-doped silicon, to PSI, and finally to a redox mediator).

In another aspect, the multilayer photoconductive organic film 16 can optionally include one or more electrochemical mediators (not shown). An electrochemical mediator can include any substance or agent capable of shuttling excited electrons from the light harvesting complex to the first electrode 12 in response to received optical energy. In one example, the electrochemical mediator can include methyl viologen. In photosynthetic systems, methyl viologen can serve as an electron acceptor from PSI (e.g., in response to irradiation, charge separation occurs within PSI on the electrode surface). Electrons are removed from the reduced iron-sulfur complex by methyl viologen and carried to the counter electrode (e.g., the first electrode 12). Electrons are resupplied to the oxidized chlorophyll dimer reaction center (P⁺₇₀₀) by its direct reduction at the working electrode (e.g., the second electrode 14). As discussed above, the inventors of the present disclosure have discovered that photocurrent increases linearly with the concentration of the electrochemical mediator, i.e., methyl viologen. Thus, in some instances, one or more layers of the photoconductive organic film 16 can include an electrochemical mediator having a concentration (in the film) sufficient to promote generation of a desired photocurrent density. It will be appreciated that the multilayer photoconductive organic film 16 can be configured such that at least one light harvesting complex is in direct contact with both of the first and second electrodes 12 and 14 when the photoconductive organic film does not include an electrochemical mediator.

In one example, the multilayer photoconductive organic film 16 can include methyl viologen at a concentration of about 0.2 M. Without wishing to be bound by theory, it is believed that methyl viologen, whose formal potential (−0.45 vs. NHE) matches the F_{b} site of PSI, enables the excited electrons to be quickly removed from the photoconductive organic film 16 and therefore produce enhanced photocurrent.

In another aspect, the multilayer photoconductive organic film 16 can be formed by depositing consecutive PSI-containing layers onto the second electrode 14 using, for example, a vacuum-assisted dropcast method, such as the one described in P N Ciesielski et al., Adv. Funct. Mater. 20:4048 (2010). For example, thylakoid membranes can be isolated from spinach leaves via maceration and subsequent centrifugation at about 4,000 g. PSI complexes can then be removed from the thylakoid membrane by adding a high concentration of surfactant, followed by further centrifugation. PSI complexes can be purified using a chilled hydroxylapatite column, and excess surfactants and salts removed using dialysis. A desired amount (e.g., 100 μL) of a PSI suspension can be pipetted onto a silicon substrate and a vacuum applied to remove any solvent. The thickness T of the multilayer photoconductive organic film 16 can be increased, for example, by adding additional deposition steps or, alternatively, decreased by diluting the concentration of the initial solution.

The biohybrid, photoelectrochemical energy conversion device 10 of the present disclosure is capable of converting optical energy (light) into electricity. Thus, the device 10 of the present disclosure can find use as a component in a variety of solid state photosensitive devices (not shown) and systems (not shown), such as photovoltaic devices and photodetection devices. In one example, the device 10 can find use as a component in a photovoltaic device. A “photovoltaic device” can include any device capable of generating electrical power by converting light (e.g., solar radiation) into electricity. In another example, the device can find use as a component in a photodetection device 10. A “photodetection device” can include any device capable of detecting the presence of light (e.g., visible light).

In some instances, the device 10 can serve as a component in optical devices, switches, sensors, logic gates, and energy sources. Electronic equipment, such as computers or remote monitoring or communications equipment can be powered by the device 10 of the present disclosure. Alternative power generation applications may involve energy storage devices so that operation can occur or continue when direct illumination from the sun or other ambient light sources is not available. Thus, in other instances, solid state photosensitive devices that incorporate the device 10 of the present disclosure can include, but are not limited to, light-powered molecular circuitry, solar batteries, optical computing and logic gates, and optoelectronic switches.

In other instances, the device 10 of the present disclosure can be incorporated into sensor devices for the detection of conditions, agents, and/or biological entities, such as bacteria and viruses. Sensors, for example, may employ biological or chemical methods evolved or designed to sensitively detect biological or chemical agents. The response may be a change in current, voltage, capacitance, inductance or absorbance. For example, the presence of an analyte (or substance to be detected) can switch on or off the photo-response or change the absorption or emission spectrum.

The following example is for the purpose of illustration only and is not intended to limit the scope of the claims, which are appended hereto.

### EXAMPLE

### Experimental

### Extraction and Isolation of PSI

PSI complexes from commercially available baby spinach were isolated using previously described methods (P N Ciesielski et al.). Briefly, thylakoid membranes were isolated from spinach leaves via maceration and subsequent centrifugation at 4,000 g (S G Reeves et al., Methods Enzymol. 69:85, 1980). The PSI complex was then removed from the thylakoid membrane by adding a high concentration of surfactant and further centrifugation. The protein was then purified using a chilled hydroxylapatite column (M. Ciobanu et al., Langmuir 21:692, 2004), and excess surfactants and salts were removed using dialysis (P N Ciesielski et al.). Using previous protein characterization methods, the concentration of the resulting PSI solution consisted of 1.7×10⁻⁴ M chlorophyll with a chlorophyll a/b ratio of 3.5, and 1.0×10⁻⁵ M protein complexes (R. Porra, Photosynth. Res. 73:149, 2002; and M. Ciobanu et al., Electroanal. Chem. 599:72, 2007).

Preparation of Silicon Substrates

Silicon substrates were purchased from either University Wafer or WRS materials. Heavily doped silicon had a doping density of 10²⁰ cm⁻³, while lightly doped silicon had a doping density of 10¹⁶ cm⁻³ (as determined by the resistivity values provided by the supplier). Substrates were cut and rinsed with deionized water prior etching with a 2% hydrogen fluoride solution to remove the native oxide layer. The etched silicon substrates were then rinsed with copious amounts of deionized water before electrochemical analysis or further modification with PSI.

Modification of Silicon Substrates with PSI

Films of PSI were deposited onto the silicon substrates following the procedure previously developed (P N Ciesielski et al.). Briefly, 100 μL of a PSI suspension was pipetted onto the silicon substrate and a vacuum was applied to remove any solvent. Due to the low surfactant concentration in the protein suspension, the resulting protein film was no longer water soluble and could withstand electrochemical experiments using aqueous mediators. The thickness of the protein film can be easily increased by adding additional deposition steps, or decreased by diluting the concentration of the initial solution. Film thicknesses were determined using a Vecco Dektak 150 stylus profilometer. For these measurements the protein film was scratched to the underlying silicon substrate, and the profilometer tip was run across the scratch. The average thickness of the films used for each experiment was determined from three measurements, and is listed in the figure caption for the various experiments.

Electrochemical Measurements

Electrochemical measurements were performed using a CH Instruments CHI 660a electrochemical workstation equipped with a Faraday cage. A custom built, three electrode cell was used. The silicon substrate was set as the working electrode, Ag/AgCl used as the reference electrode, and a platinum mesh used as a counter electrode. Electrochemical mediator solutions consisted of 100 mM potassium chloride (Sigma-Aldrich) and 0.2 mM of either ferrocyanide (Sigma-Aldrich), ferricyanide (Fisher), ruthenium hexamine (Sigma-Aldrich), or methyl viologen (Sigma-Aldrich). The concentration of methyl viologen was varied for different experiments.

Photochronoamperometric experiments were performed at the open circuit potential of system, which was determined experimentally for each sample. Illumination was provided using a 250 W cold light source (Leica KL 2500 LCD) equipped with a 633 nm high pass filter, generating a light intensity of 0.19 W/cm². The photocurrent values reported were found by taking the difference in the dark current and the current under illumination after 10 seconds. Values reported represent the average value from four measurements, with error bars representing the standard deviation between those measurements.

Photovoltage measurements were performed by measuring the open circuit potential of the system in the dark and under illumination. The raw data for one of these experiments can be seen in the supporting information.

### Results

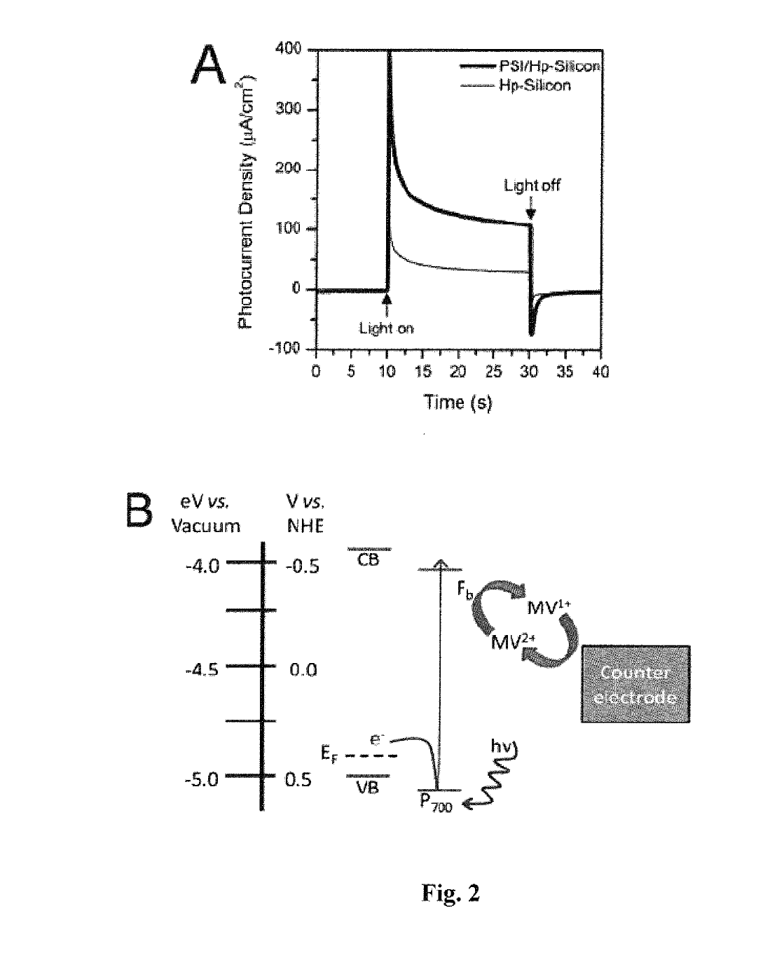

Using heavily P-doped silicon (Hp-Silicon), we found that a significant photocurrent enhancement could be achieved when a film of PSI was deposited on the semiconductor (FIG. 2A). We attributed this tremendous photocurrent enhancement to the band alignment between the valence band (VB) of the silicon with the P₇₀₀ reaction center of PSI (FIG. 2B). Thus, the ideal band alignment for this system (ignoring the effects of band bending) enables electrons to flow from the P-doped silicon to the P₇₀₀ reaction center of PSI. Photons are then used by PSI to excite the electron to the F_{b} site, where a methyl viologen redox mediator is used to shuttle the excited electrons to the counter electrode.

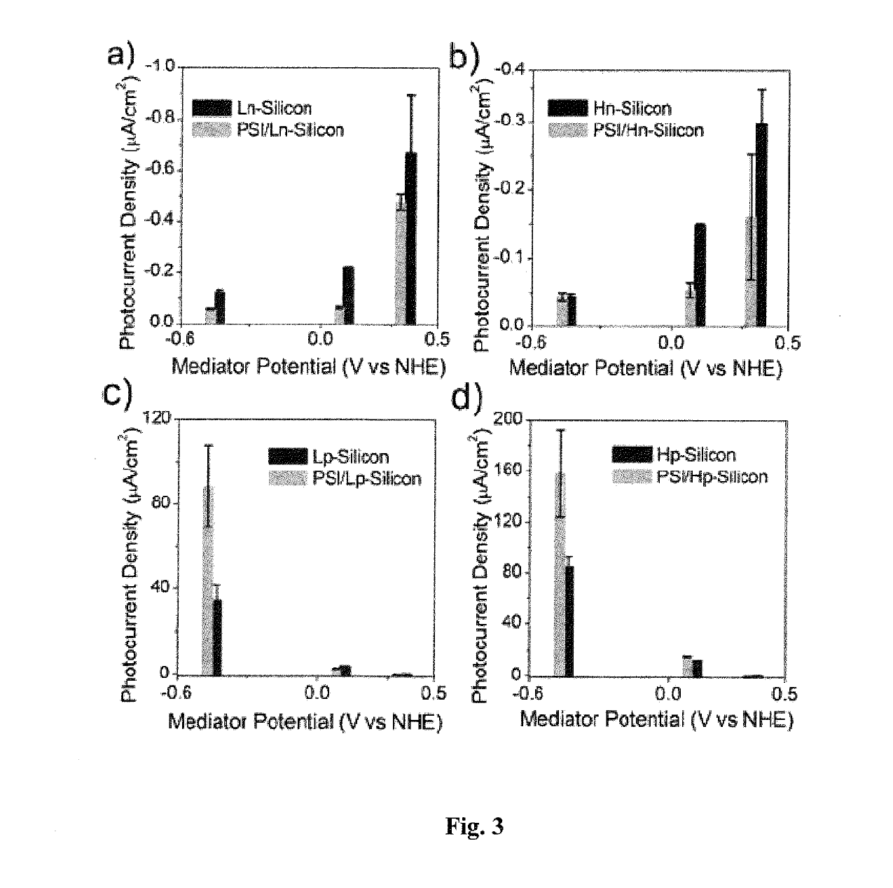

In order to test this hypothesis, a systematic evaluation of the doping type, doping density, and mediator formal potential was performed. As seen in FIGS. 3A-D, the direction of electron flow was controlled by the doping type of the system. For N-doped silicon, only photo-oxidations occur at the electrode, while only photo-reductions occur when P-doped silicon is used as the working electrode. Photocurrent enhancement with PSI was only observed, however, for P-doped silicon. This provides further evidence for the scheme depicted in FIG. 2B, where the electrons can flow “down-hill” from P-doped silicon to the P₇₀₀ reaction center of PSI, but are unable to flow “up-hill” from the F_{b} site of PSI into N-doped silicon. Furthermore, the mediator was found to have a profound effect on the resulting photocurrent in the system. The mediators tested included ferri/ferro-cyanide, ruthenium hexamine, and methyl viologen with redox formal potentials of 0.36, 0.1, and −0.45 vs NHE respectively. The greatest photocurrent enhancement was observed when methyl viologen was used, where the formal potential of the redox mediator (−0.45 vs NHE) matches the F_{b} site of PSI, enabling the excited electrons to be quickly removed from the protein film.

Once the ideal silicon substrate and redox mediator were determined, the effect of the thickness of the protein film and the concentration of the redox mediator was analyzed. Previous studies that utilized a gold substrate demonstrated that the photocurrent increased with protein film thickness beyond 2 μm (P N Ciesielski et al.). In our experiments on silicon, however, we found that protein film thicknesses roughly greater than 1 μm did not generate greater photocurrents, and in fact began to decrease the photocurrent density with a film thickness greater than 2 μm (FIG. 5). Thus, in order to maximize the synergistic effects between the silicon and PSI, a balance between the light absorbed by the protein film and the light reaching the photoactive substrate must be achieved.

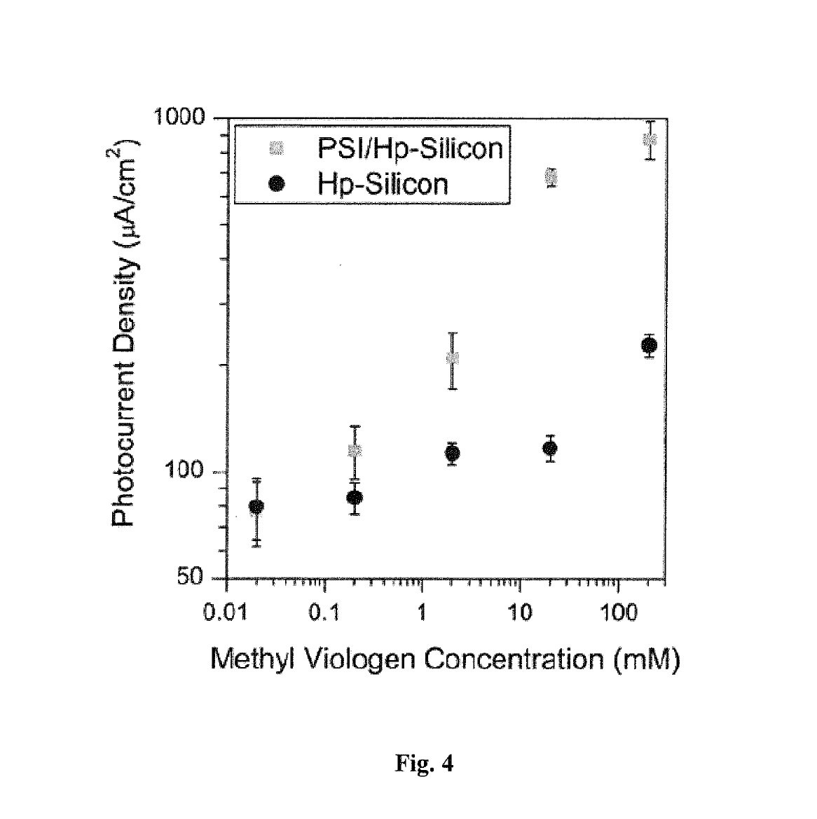

As seen in FIG. 4, the photocurrent increases linearly with mediator concentration, and the photocurrent enhancement improves dramatically with the concentration of methyl viologen. At the highest concentration tested (0.2 M), an average photocurrent density of 875 μA/cm² was observed. This is one of the highest reported photocurrent densities for a film of PSI deposited onto an electrode. As a control, the photocurrent for unmodified silicon was measured. The less dramatic increase in photocurrent observed for the unmodified electrode demonstrates how PSI can be used to enhance the photocurrent of P-doped silicon.

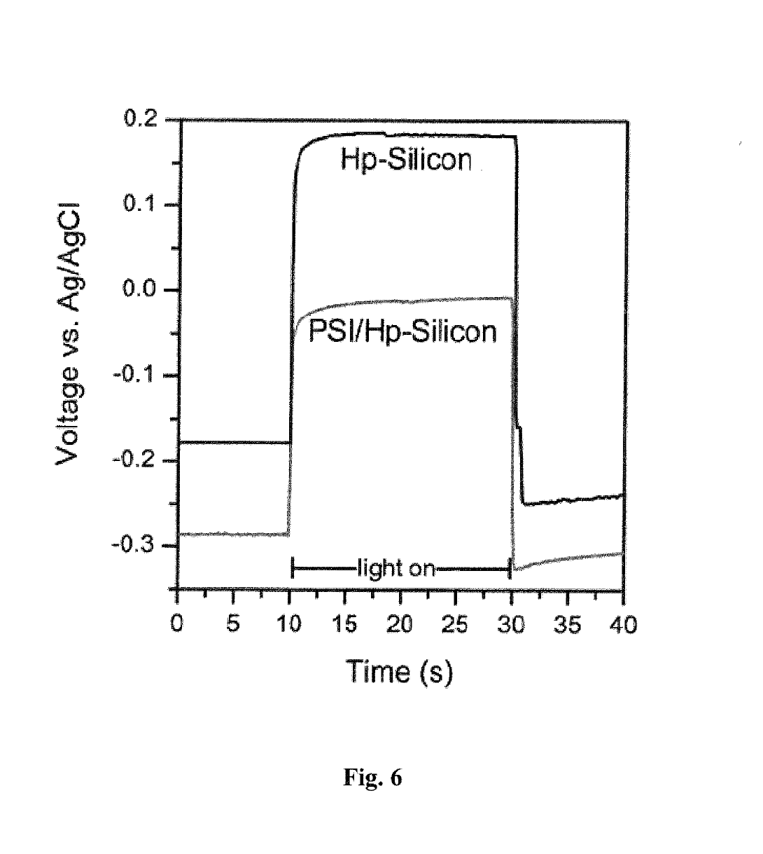

Finally, open circuit voltage measurements were performed in order to determine the effect that the protein modification had on the photovoltage of the system (FIG. 6). The PSI modified silicon was found to retain approximately 80% of photovoltage observed for the unmodified P-doped silicon (0.28 V vs. 0.35 V). This small decrease in photovoltage can be attributed to the voltage required to pass electrons through the protein film. The four-fold enhancement in photocurrent, coupled with the minimal reduction in photovoltage makes this system particularly attractive.

From the above description of the present disclosure, those skilled in the art will perceive improvements, changes and modifications. Such improvements, changes, and modifications are within the skill of those in the art and are intended to be covered by the appended claims. All patents, patent applications, and publication cited herein are incorporated by reference in their entirety.

The following is claimed:

1. A biohybrid, photoelectrochemical energy conversion device comprising:
a first electrode;
a second electrode comprising a semiconductor material; and
a multilayer, photoconductive organic film interposed between the first and second electrodes, each layer of the photoconductive organic film including at least one light harvesting complex.

2. The device of claim 1, wherein the first electrode comprises an N-doped semiconductor material.

3. The device of claim 1, wherein the first electrode is configured for admittance of light to the multilayer photoconductive organic film.

4. The device of claim 1, wherein the second electrode comprises P-doped silicon.

5. The device of claim 4, wherein the second electrode comprises heavily P-doped silicon.

6. The device of claim 5, wherein the second electrode is doped at a density of about 10¹⁶ cm⁻³.

7. The device of claim 1, wherein the second electrode is a carbon allotrope.

8. The device of claim 7, wherein the carbon allotrope is graphene.

9. The device of claim 1, wherein the light harvesting complex is derived from a photosynthetic organism.

10. The device of claim 1, wherein the light harvesting complex is Photosystem I or Photosystem II.

11. The device of claim 1, wherein at least one of the multilayer photoconductive organic film includes an electrochemical mediator for shuttling excited electrons to the first electrode in response to received optical energy.

12. The device of claim 1, serving as a component in a device selected from the group consisting of a photovoltaic device and a photodetection device.

13. The device of claim 1, wherein the multilayer photoconductive organic film has a thickness of about 0.5 μm to about 3 μm.
